(19) United States
(12) Patent Application Publication
(10) Pub. No.: US 2023/0247819 A1
(43) Pub. Date: Aug. 3, 2023

(54) SEMICONDUCTOR DEVICES HAVING SHIELDING ELEMENTS

(71) Applicant: Yangtze Memory Technologies Co., Ltd., Wuhan (CN)

(72) Inventors: Chao SUN, Wuhan (CN); Ning JIANG, Wuhan (CN); Wei LIU, Wuhan (CN)

(73) Assignee: Yangtze Memory Technologies Co., Ltd., Wuhan (CN)

(21) Appl. No.: 18/159,430

(22) Filed: Jan. 25, 2023

(30) Foreign Application Priority Data
Jan. 28, 2022 (CN) 2022101083896

(51) Int. Cl. H10B 12/00

(52) U.S. Cl. CPC H10B 12/05; H10B 12/33; H10B 12/31

(57) ABSTRACT

A semiconductor device is provided. For example, the semiconductor device can include a plurality of transistors that are arranged in an array in an X-Y plane. Each of the transistors can include a channel extending in Z direction. The semiconductor device can further include a plurality of word lines. Each of the word lines can electrically connect neighboring some of the transistors that are arranged in a column in X direction at lateral walls of the channels thereof. The semiconductor device can further include one or more electromagnetic shielding elements. At least one of the electromagnetic shielding elements can be disposed between neighboring two of the transistors that are disposed in a row in Y direction.

### CROSS REFERENCE TO RELATED APPLICATIONS

This application claims the priority of CN application no. 2022101083896, filed Jan. 28, 2022, which is hereby incorporated by reference in its entirety.

### TECHNICAL FIELD

The present disclosure relates to semiconductor memory, and, more specifically, to semiconductor device having shielding elements.

### BACKGROUND

As critical dimensions of devices in integrated circuits shrink to the limits of common memory cell technologies, designers have been looking to techniques for stacking multiple planes of memory cells to achieve greater storage capacity, and to achieve lower costs per bit. A 3D NAND memory device is an exemplary device of stacking multiple planes of memory cells to achieve greater storage capacity, and to achieve lower costs per bit. The 3D NAND memory device can include a stack of alternating insulating layers and word line layers over a substrate and a slit structure.

### SUMMARY

Aspects of the present disclosure provide a method for manufacturing a semiconductor device. For example, the method can include forming a plurality of transistors that are arranged in an array in an X-Y plane. Each of the transistors can include a channel extending in Z direction. The method can further include forming a plurality of word lines. Each of word lines can electrically connect neighboring some of the transistors at lateral walls of the channels thereof. The neighboring some of the transistors can be arranged in a column in X direction. The method can further include forming one or more electromagnetic shielding elements. Each of electromagnetic shielding elements can be disposed between neighboring two of the transistors that are disposed in a row in Y direction.

In an embodiment, each of the transistors can further include a source disposed on a first end of the channel and a drain disposed on a second end of the channel, and the electromagnetic shielding element can have a projection onto the channel in Y direction that does not overlap the source and the drain. In another embodiment, the electromagnetic shielding element can be shorter in Z direction than the channels of the neighboring two transistors. In some embodiments, the electromagnetic shielding element can be further disposed between neighboring two of the transistors that are disposed in the column.

In an embodiment, each of the channels of the transistors can be rectangular pillar-shaped, and each of the word lines can be formed at a lateral wall of a corresponding one of the rectangular pillar-shaped channels. For example, the lateral walls of the rectangular pillar-shaped channels of the neighboring two transistors on which the word lines are formed can face opposite directions.

In an embodiment, the method can further include forming an electromagnetic shielding contact pad that is connected to one of the electromagnetic shielding elements, and forming a word line contact pad that is connected to one of the word lines that neighbors the electromagnetic shielding element. The electromagnetic shielding contact pad and the word line contact pad can be disposed at opposite sides of the array in X direction. In an embodiment, the electromagnetic shielding elements and the word lines can be formed by forming first grooves in a substrate of the semiconductor device at a back side thereof for contact pads to be formed therein, and filling the first grooves with an oxide, forming in the substrate second grooves and third grooves for the word lines and the electromagnetic shielding elements to be formed therein, respectively, the third grooves being in contact with the first grooves, filling the second grooves with a first conductor to form the word lines, thinning the back side of the semiconductor device to expose the oxide filled in the first grooves, recessing the oxide to expose lateral walls of the third grooves, and filling the third grooves and the first grooves with a second conductor to form the electromagnetic shielding elements and the contact pads, respectively.

Aspects of the present disclosure also provide a semiconductor device. For example, the semiconductor device can include plurality of transistors that are arranged in an array in an X-Y plane. Each of the transistors can include a channel extending in Z direction. The semiconductor device can further include a plurality of word lines. Each of the word lines can electrically connect neighboring some of the transistors that are arranged in a column in X direction at lateral walls of the channels thereof. The semiconductor device can further include one or more electromagnetic shielding elements. Each of the electromagnetic shielding elements can be disposed between neighboring two of the transistors that are disposed in a row in Y direction.

In an embodiment, each of the transistors can further include a source disposed on a first end of the channel and a drain disposed on a second end of the channel, and the electromagnetic shielding element can have a projection onto the channel in Y direction that does not overlap the source and the drain. In another embodiment, the electromagnetic shielding element can be shorter in Z direction than the channels of the neighboring two transistors. In some embodiments, the electromagnetic shielding element can be further disposed between neighboring two of the transistors that are disposed in the column.

In an embodiment, each of the channels of the transistors can be rectangular pillar-shaped, and each of the word lines can be formed at a lateral wall of a corresponding one of the rectangular pillar-shaped channels. For example, the lateral walls of the rectangular pillar-shaped channels of the neighboring two transistors on which the word lines are formed can face opposite directions.

In an embodiment, the semiconductor device can further include an electromagnetic shielding contact pad connected to one of the electromagnetic shielding elements, and a word line contact pad connected to one of the word lines that neighbors the electromagnetic shielding element. The electromagnetic shielding contact pad and the word line contact pad can be disposed at opposite sides of the array in X direction.

In an embodiment, at least one of the electromagnetic shielding elements can include a plurality of electromagnetic shielding segments that are separated from one another. For example, the electromagnetic shielding segments can be arranged along X direction, Y direction and/or Z direction.

In an embodiment, at least one of the electromagnetic shielding elements can be applied with a first voltage that is less than a second voltage applied to a corresponding one of the channels. In some embodiments, at least one of the electromagnetic shielding elements can be applied with a voltage such that a first transistor of the neighboring two transistors, between which the electromagnetic shielding element is disposed, is less affected by a combination of a first electromagnetic field generated by the electromagnetic shielding element with a second electromagnetic field generated by a second transistor of the neighboring two transistors than affected by the second electromagnetic field.

Aspects of the present disclosure further provide a memory system. For example, the memory system can include a semiconductor device and control circuitry coupled to the semiconductor device. The control circuitry can be configured for controlling operations of the semiconductor device. The semiconductor device can include a plurality of transistors that are arranged in an array in an X-Y plane. Each of the transistors can include a channel extending in Z direction. The semiconductor device can further include a plurality of word lines. Each of the word lines can electrically connect neighboring some of the transistors that are arranged in a column in X direction at lateral walls of the channels thereof. The semiconductor device can further include one or more electromagnetic shielding elements. Each of the electromagnetic shielding elements can be disposed between neighboring two of the transistors that are disposed in a row in Y direction.

### BRIEF DESCRIPTION OF THE DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A is a schematic diagram of a planar transistor;

FIG. 1B is a schematic diagram of a buried channel transistor;

FIG. 2 is a schematic diagram of a semiconductor device according to some embodiments of the present disclosure;

FIG. 3 is a cross-sectional view of a semiconductor device according to some embodiments of the present disclosure;

FIG. 4 is a flow chart of a method for manufacturing a semiconductor device according to some embodiments of the present disclosure;

FIG. 4A is a top view illustrating the formation of pillar-shaped channels of the semiconductor device according to some embodiments of the present disclosure;

FIG. 4B is a schematic diagram illustrating the formation of pillar-shaped channels of the semiconductor device according to some embodiments of the present disclosure;

FIG. 4C is a top view illustrating the formation of an insulating layer of the semiconductor device according to some embodiments of the present disclosure;

FIG. 4D is a top view illustrating the formation of second grooves and third grooves of the semiconductor device according to some embodiments of the present disclosure;

FIG. 4E is a top view illustrating the formation of gate oxidization layers of the semiconductor device according to some embodiments of the present disclosure;

FIG. 4F is a top view illustrating the formation of electromagnetic shielding elements and word lines of the semiconductor device according to some embodiments of the present disclosure;

FIG. 5 is a cross-sectional view of a semiconductor device according to some embodiments of the present disclosure;

FIG. 6A is a top view illustrating the formation of pillar-shaped channels of the semiconductor device according to some embodiments of the present disclosure;

FIG. 6B is a top view illustrating the formation of insulating layers of the semiconductor device according to some embodiments of the present disclosure;

FIG. 6C is a top view illustrating the formation of second grooves and third grooves of the semiconductor device according to some embodiments of the present disclosure;

FIG. 6D is a top view illustrating the formation of gate oxidization layers of the semiconductor device according to some embodiments of the present disclosure;

FIG. 6E is a top view illustrating the formation of metal layers and gates of the semiconductor device according to some embodiments of the present disclosure;

FIG. 7 is a cross-sectional view of a semiconductor device according to some embodiments of the present disclosure;

FIG. 8 is a top view illustrating the formation of contact pads of the semiconductor device according to some embodiments of the present disclosure;

FIG. 9 is a top view illustrating the formation of another contact pads of the semiconductor device according to some embodiments of the present disclosure;

FIG. 9A is a top view illustrating the formation of yet another contact pads of a semiconductor device according to some embodiments of the present disclosure;

FIGS. 10A to 10H are cross-sectional views of semiconductor devices that have electromagnetic shielding elements in various configurations according to some embodiments of the present disclosure;

FIGS. 11A to 11E are various cross-sectional views of semiconductor devices that that have electromagnetic shielding elements in various configurations according to some embodiments of the present disclosure;

FIGS. 12A to 12C are cross-sectional views illustrating manufacturing semiconductor devices according to some embodiments of the present disclosure; and

FIG. 13 shows a block diagram of a memory system according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features may be in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other embodiments whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−0.10%, .+−0.20%, or .+−0.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

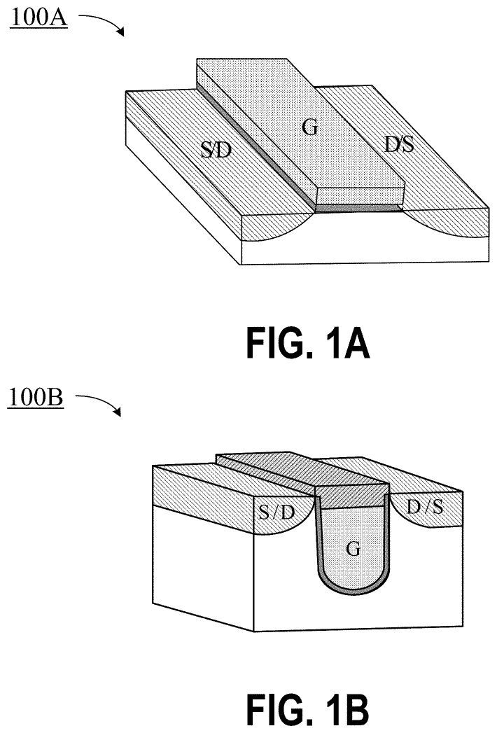

In related arts, array transistors of mainstream memory include planar array transistors and buried channel array transistors (BCATs). FIGS. 1A and 1B are schematic diagrams showing a planar array transistor 100A and a BCAT 100B, respectively. As shown in FIG. 1A, a transistor of the planar array transistor 100A includes a gate G and a source S(/D) and a drain D(/S) that are formed at two substantially horizontal sides of the gate G. As shown in FIG. 1B, a transistor of the BCAT 100B includes a gate G and a source S(/D) and a drain D(/S) that are also formed at two substantially horizontal sides of the gate G. As the source S(/D) and the drain D(/S) occupy locations that do not overlap the gate G, the planar array transistor 100A and the BCAT 100B each have a large area.

In the planar array transistor 100A and the BCAT 100B, as the source S(/D) and the drain D(/S) are located at two substantially horizontal sides of the gate G, bit lines (BLs) and capacitors of the memory have to be located at the same side as the gate G. In subsequent processes, the BLs, the transistors and the capacitors have to be connected to one another, and the transistors have to be further connected to word lines (WLs). Therefore, the planar array transistor 100A and the BCAT 100B each have complicated circuit layout and are difficult to be manufactured.

In the planar array transistor 100A of FIG. 1A and the BCAT 100B of FIG. 1B, only one transistor is shown. According to the present disclosure, the planar array transistor 100A and the BCAT 100B can include any number of transistors.

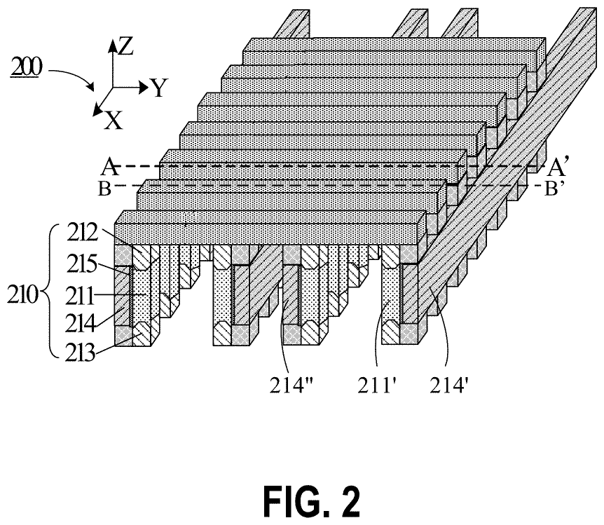

Aspects of the present disclosure provide a semiconductor device. Please refer to FIG. 2, which is a schematic diagram of a semiconductor device 200 according to some embodiments of the present disclosure. The semiconductor device 200 can include a plurality of transistors 210 that are arranged in an array in an X-Y plane. For example, the array can include a plurality of rows that are arranged along a first direction, e.g., X direction, and a plurality of columns that intersect the rows and are arranged along a second direction, e.g., Y direction. Each of the transistors 210 can include a channel 211, and the channels 211 of the transistors 210 are arranged along the first direction and the second direction in the array. In an embodiment, each of the channels 211 can be in the shape of a pillar and can extend along a third direction, e.g., Z direction, that is perpendicular to a plane defined by the first direction and the second direction. For example, the pillar can have a cross section in the shape of a rectangle, a circle, rhombus, or any other polygons. In an embodiment, the pillar-shaped channels 211 in each of the columns of the array can be formed at lateral walls thereof with an oxidization layer 215 and a word line 214 sequentially, both of which extend along the first direction, e.g., X direction, and be thus connected to one another by the word line 214. In an embodiment, a source 212 and a drain 213 can be formed on two ends of each of the pillar-shaped channels 211, respectively. In some embodiments, the sources 212 and the drains 213 are interchangeable. As the source 212 and the drain 213 are formed on the two ends of each of the pillar-shaped channels 211, rather than formed at two sides of each of the word lines (i.e., gates) 214, the semiconductor device 200 has a greater transistor density, as compared with a semiconductor device including the planar semiconductor device 100A or the BCAT 100B, each of which includes transistors each having a source and a drain that are formed at substantially horizontal sides of a gate, as shown in FIGS. 1A and 1B.

In the semiconductor device 200, in which each of the word lines 214 is formed on only one lateral wall of a corresponding one of the pillar-shaped channels 211, any one of the pillar-shaped channels 211, e.g., a rectangular pillar-shaped channel 211′, that is coupled to a non-selected word line 214, e.g., a word line 214′, that neighbors a selected word line, e.g., a word line 214″, will be affected by the selected word line 214″. For example, the activities of the neighboring selected word line 214″ can change the charges accumulated in the transistor that includes the channel 211′, which is connected to the non-selected word line 214′, and the information stored in the transistor may be affected by a so-call Row Hammer effect.

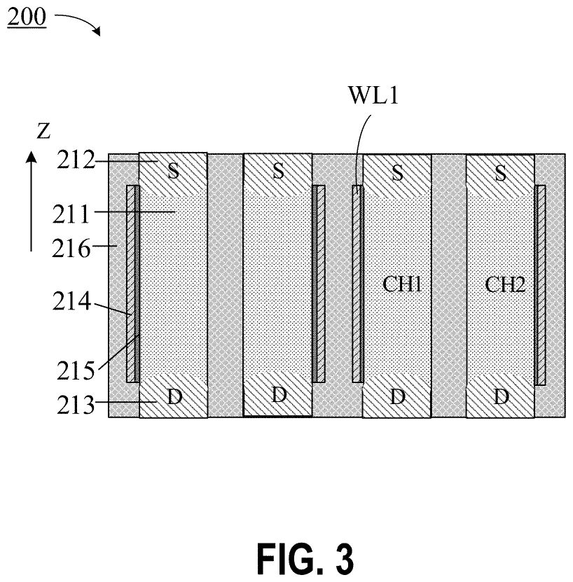

Refer to FIG. 3, which is a cross-sectional view of the semiconductor device 200 of FIG. 2 along a cut line BB′. When a selected word line WL1 connected to a rectangular pillar-shaped channel CH1 is activated, another rectangular pillar-shaped channel CH2 that neighbors the pillar-shaped channel CH1 will be interfered, and, as a result, the performance of the semiconductor device 200 is affected. Further improvement to the semiconductor device 200 is thus required

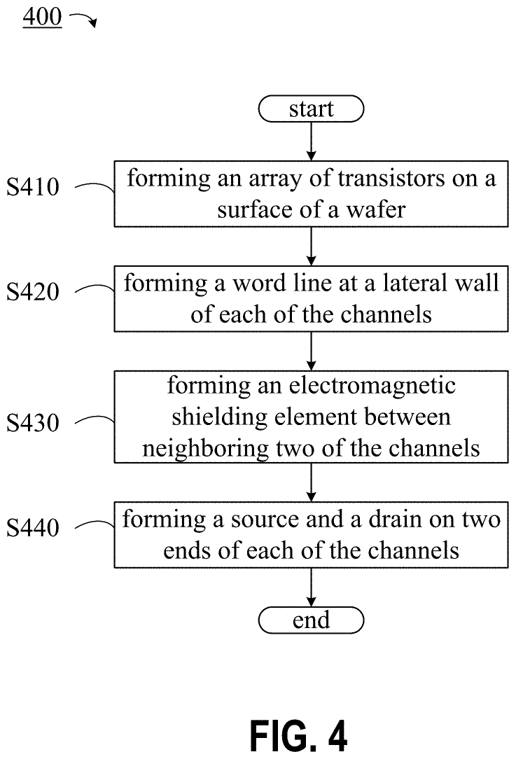

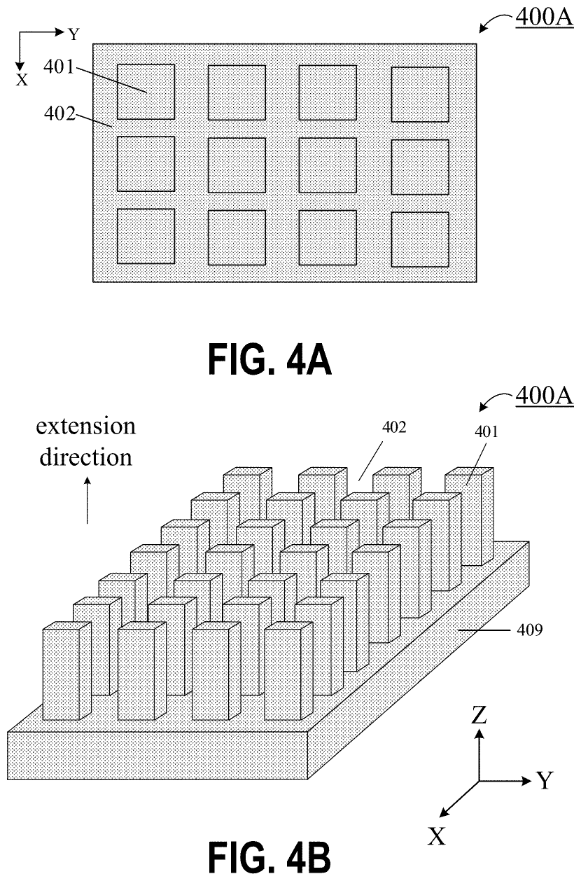

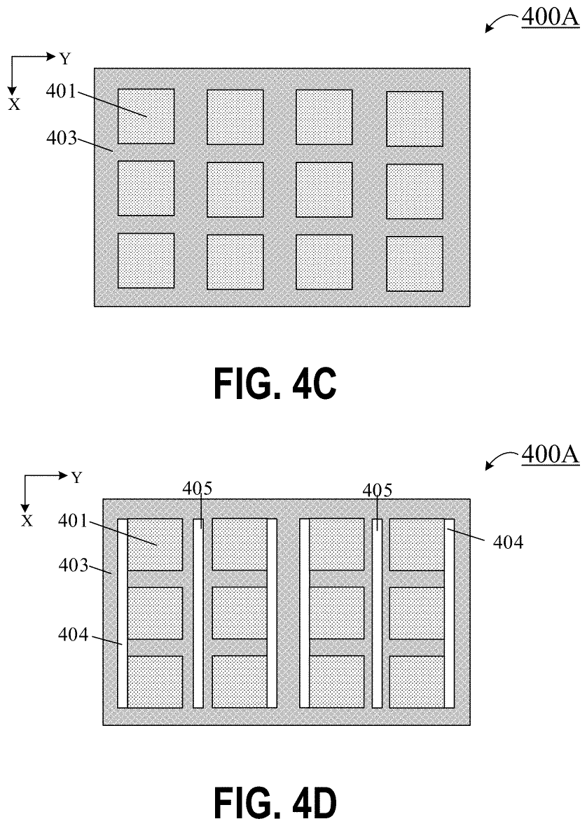

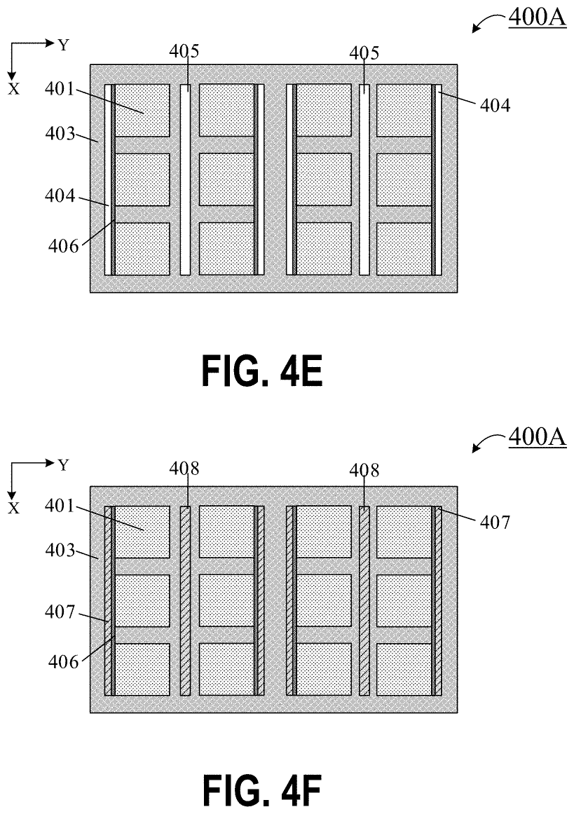

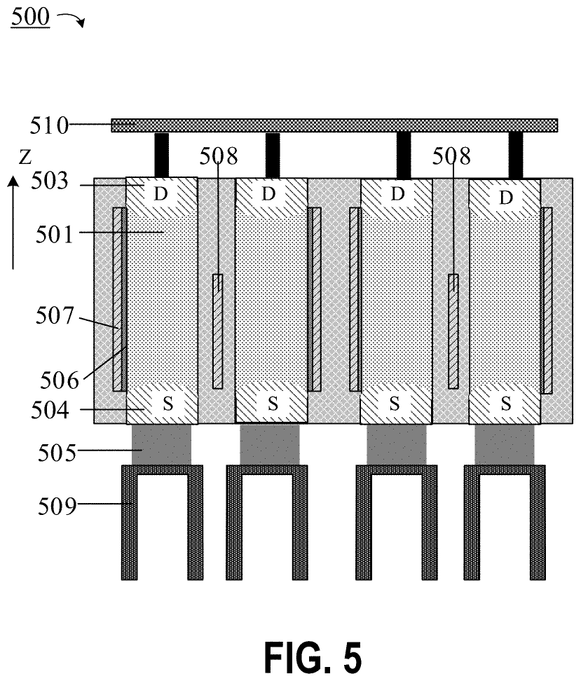

Aspects of the present disclosure provide a method for manufacturing a semiconductor device. FIG. 4 is a flow chart of a method 400 for manufacturing a semiconductor device, e.g., a semiconductor device 400A shown in FIGS. 4A to 4F or a semiconductor device 500 shown in FIG. 5, according to some embodiments of the present disclosure. The method 400 can include steps S410 to S440.

At step S410, a plurality of transistors, e.g., transistors of the semiconductor device 400A, are formed on a surface of a wafer, e.g., a wafer 409 shown in FIG. 4A. In an embodiment, the transistors can be arranged in an array, and the array can include a plurality of rows that are arranged along a first direction, e.g., X direction, that is parallel to the surface of the wafer 409, and a plurality of columns that intersect the rows and are arranged along a second direction, e.g., Y direction, that is parallel to the surface of the wafer 409. For example, the first direction and the second direction can include an included angle less than or equal to 90 degrees. Each of the transistors can include a channel, e.g., a channel 401 shown in FIG. 4A, extending in a third direction, e.g., Z direction, that is perpendicular to the first direction, the second direction and the surface of the wafer 409. In some embodiments, at least one of the channels 401 can be in the shape of a pillar. In an embodiment, the pillar can have a cross section in the shape of a rectangle, a rhombus, a circle, or any other polygons. For example, the pillared-shaped channels 401 can extend in the third direction, which is perpendicular to a plane defined by the first direction and the second direction, e.g., the surface of the wafer 409.

At step S420, a plurality of word lines, e.g., word lines 407 shown in FIG. 4F, are formed on lateral walls of the pillar-shaped channels 401 of the transistors. In an embodiment, each of the word lines 407 can electrically connect one or more of the transistors that neighbor to each other and are arranged in a column in the first direction, e.g., X direction, at lateral walls thereof. In an embodiment, the word lines 407 each extend along and are parallel to X direction and are arranged along Y direction.

At step S430, an electromagnetic shielding element, e.g., an electromagnetic shielding element 408 shown in FIG. 4F, is formed between at least neighboring two of the pillar-shaped channels 401 of the transistors that are arranged in a row in Y direction. In an embodiment, the electromagnetic shielding element 408 can extend along X direction.

At step S440, a source and a drain, e.g., a source 504 and a drain 503 shown in FIG. 5, are formed on two ends of each of the pillar-shaped channels 401 of the transistors. In some embodiments, the electromagnetic shielding element 504 has a projection onto the channel 211 in Y direction that does not overlap the source 212 and the drain 213.

In an embodiment, the wafer 409 can be a single crystal silicon material, e.g., a single crystal silicon ingot, that is used to manufacturing the semiconductor device 400A. The single crystal silicon ingot, e.g., in the shape of a cylinder, can be ground, polished and diced to form a plurality of round silicon plates, i.e., wafers. In another embodiment, the wafer 409 can have two opposite round surfaces, one of which is the above-mentioned surface of the wafer 409, and the other of which can be referred to as a backside surface of the wafer 409 according to some embodiments of the present disclosure.

FIGS. 4A to 4F illustrate the manufacturing of a semiconductor device, e.g., the semiconductor device 400A, at intermediate stages according to some embodiments of the present disclosure. In the semiconductor device 400A, word lines are formed on lateral walls of any two neighboring transistors (or channels) that face different directions.

FIG. 4A is a top view of the semiconductor device 400A illustrating the formation of channels of transistors of the semiconductor device 400A according to some embodiments of the present disclosure. As shown in FIG. 4A, a plurality of channels 401 that are arranged in an array in an X-Y plane, for example, are formed on a surface of a wafer 409. For example, the array can include a plurality of rows that are arranged along a first direction, e.g., X direction, and a plurality of columns that intersect the rows and are arranged along a second direction, e.g., Y direction. In an embodiment, each of the channels 401 can be in the shape of a pillar, e.g., a rectangular pillar, and each of the rectangular pillar-shaped channels 401 can extend along a third direction, e.g., Z direction, that is perpendicular to a plane defined by the first direction and the second direction, as shown in FIG. 4B, which is a schematic diagram illustrating the formation of the pillar-shaped channels 401 of the semiconductor device 400A according to some embodiments of the present disclosure.

In some embodiments, the pillar-shaped channels 401 can be formed on the surface of the wafer 409 by covering the wafer 409 with a mask (not shown) that covers a certain area of the wafer 490 that is used to form the pillar-shaped channels 401, etching the wafer 409 to a certain depth, which is less than the thickness of the wafer 409, to form the first grooves 402, and removing the mask to form the pillar-shaped channels 401 with their lateral walls exposed. In some embodiments, the wafer 409 can be etched by using photolithography (PH) or dry etching (ET), e.g., electron beam lithography, plasma etching and reactive ion etching (ME).

FIG. 4C is a top view illustrating the formation of an insulating layer of the semiconductor device 400A according to some embodiments of the present disclosure. In some embodiments, an insulating material, e.g., SiO₂, can be deposited in the first grooves 402 to form an insulating layer 403 that covers the first grooves 402 and the lateral walls of the pillar-shaped channels 401. In some embodiments, a chemical mechanical polishing (CMP) can then be employed to polish and remove the residual of the insulating material to expose top surfaces of the pillar-shaped channels 401.

FIG. 4D is a top view illustrating the formation of second grooves and third grooves of the semiconductor device 400A according to some embodiments of the present disclosure. In an embodiment, the insulating layer 403 can be etched to form second grooves 404 that expose one of the lateral walls of each of the pillar-shaped channels 401, e.g., the rectangular pillar-shaped channels 401, and third grooves 405, each of which is disposed between two neighboring transistors (i.e., two neighboring rectangular pillar-shaped channels 401) in a row in Y direction. In some embodiments, each of the second grooves 404 exposes the lateral walls of the pillar-shaped channels 401 of the transistors that neighbor to each other and are arranged in a column in X direction. In an embodiment, the lateral walls of the two neighboring rectangular pillar-shaped channels 401 that are exposed by the corresponding two of the second grooves 404 can face opposite directions, as shown in FIG. 4D. In another embodiment, the lateral walls of the two neighboring rectangular pillar-shaped channels 401 that are exposed by the corresponding two of the second grooves 404 can face the same direction. In some embodiments, the third groove 405 and each of the two second grooves 404, between which the third groove 405 is disposed, are disposed at opposite lateral walls of the rectangular pillar-shaped channels 401, as shown in FIG. 4D.

FIG. 4E is a top view illustrating the formation of gate oxidization layers of the semiconductor device 400A according to some embodiments of the present disclosure. In an embodiment, the lateral walls of the rectangular pillar-shaped channels 401 that are exposed by the second grooves 404 can be oxidized, e.g., by direct oxidization, alkaline oxidization or acidic oxidization, to form gate oxidization layers 406 on the exposed lateral walls of the rectangular pillar-shaped channels 401. For example, the lateral walls of the rectangular pillar-shaped channels 401 that are exposed by the second grooves 404 can be heated and oxidized directly, so that silicon in the lateral walls reacts with air containing an oxidizing material in a high temperature to form a silicon dioxide film, i.e., the gate oxidization layers 460, on the lateral walls of the rectangular pillar-shaped channels 401. In some embodiments, the gate oxidization layers 406 can include an insulation material, such as silicon dioxide (SiO₂).

FIG. 4F is a top view illustrating the formation of electromagnetic shielding elements and word lines of the semiconductor device 400A according to some embodiments of the present disclosure. In an embodiment, the third grooves 405 and the second grooves 404 can be filled with a metal material, to form electromagnetic shielding elements 408 and word lines (or gates) 407, respectively. Therefore, the word lines 407 and the electromagnetic shielding elements 408 can be formed in a single deposition step. In some embodiment, the metal material can include, but are not limited to tungsten (W), cobalt (Co), copper (Cu), aluminum (Al), or other suitable metal materials. In an embodiment, the electromagnetic shielding elements 408 can be made of polysilicon. In an embodiment, each of the word lines 407 can electrically connect neighboring some of the transistors that are arranged in a column in X direction at the lateral walls of the pillar-shaped channels 401 thereof. In an embodiment, the gate oxidization layers 406 are disposed between the pillar-shaped channels 401 and the word lines 407 to isolate the word line 407 from the pillar-shaped channels 401 and prevent charge leakage. In an embodiment, the lateral walls of the two neighboring rectangular pillar-shaped channels 401 at which the word lines 407 are disposed can face opposite directions, as shown in FIG. 4F. In another embodiment, the lateral walls of the two neighboring rectangular pillar-shaped channels 401 at which the word lines 407 are disposed can face the same direction. In some embodiments, the electromagnetic shielding element 408 and each of the two word lines 407, between which the electromagnetic shielding element 408 is disposed, are disposed at opposite lateral walls of the rectangular pillar-shaped channels 401, as shown in FIG. 4F. The electromagnetic shielding elements 408 can prevent the neighboring pillar-shaped channels 410 from interfering with each other, and reduce the coupling effect occurring between the word lines 407 and the pillar-shaped channels 401. The word lines 407 can be applied with word line voltages, and the transistors connected thereto can be enabled or disabled.

In some embodiments, bit lines can be formed to connect the sources or the drains of the transistors. Storage capacitors are further formed to store data written into the semiconductor device 400A. Each of the storage capacitors has a first electrode connected to the drain or the source of a corresponding one of the transistor, and a second electrode connected to a common terminal. In an embodiment, the common terminal can be connected to a low voltage, e.g., 0.5V. In another embodiment, the common terminal can be grounded. In an embodiment, the electromagnetic shielding elements 408 can be made of a metal material that has a high work function, such that the electromagnetic shielding elements 408 can have an even lower voltage.

In an embodiment, at least one of the electromagnetic shielding elements 408 can be applied with a first voltage that is less than a second voltage applied to a corresponding one of the channels 401. In another embodiment, the electromagnetic shielding element 408 can be disposed in a middle region between the neighboring two transistors, and the first voltage can be less than a half of the second voltage. In some embodiments, at least one of the electromagnetic shielding elements can be applied with a voltage such that a first transistor of the neighboring two transistors, between which the electromagnetic shielding element 408 is disposed, is less affected by a combination of a first electromagnetic field generated by the electromagnetic shielding element 408 with a second electromagnetic field generated by a second transistor of the neighboring two transistors than affected by the second electromagnetic field.

In an embodiment, the electromagnetic shielding elements 408 can be connected to the common terminal. In another embodiment, the electromagnetic shielding elements 408 can be disconnected with the common terminal, and supplied with a voltage independently.

In some embodiments, the second grooves 404 can be greater than the third grooves 405 in etching depth. The etching depths of the second grooves 404 and the third grooves 405 can be controlled by determining various etching parameters, such as etching time, gas flow rate, gas flow proportion, pressure and temperature. For example, under a constant etching rate, the longer the etching time is, the deeper the grooves formed in the third direction become, e.g., Z direction. In an embodiment, the second grooves 404 can have a greater etching depth than the third grooves 405 by controlling the etching parameters. The second grooves 404 and the third grooves 405 can be formed by dry etching, e.g., plasma etching.

In some embodiments, the first direction and the second direction can include an included angle that is less than or equal to 90 degrees.

FIG. 5 is a cross-sectional view of a semiconductor device 500 according to some embodiments of the present disclosure. The semiconductor device 500 can be manufactured by the method 400. In an embodiment, the semiconductor device 500 can include a plurality of transistors arranged in an array in an X-Y plane, and each of the transistors can include a channel, e.g., a pillar-shaped channel 501. For example, the array can include a plurality of rows that are arranged along a first direction, e.g., X direction, and a plurality of columns that intersect the rows and are arranged along a second direction, e.g., Y direction. Each of the transistors can include a channel 501, and the channels 501 of the transistors are arranged along the first direction and the second direction in the array. In an embodiment, each of the channels 501 can be in the shape of a pillar, and extend along a third direction, e.g., Z direction, that is perpendicular to a plane defined by the first direction and the second direction. For example, the pillar can have a cross section in the shape of a rectangle, a circle, rhombus, or any other polygons. In an embodiment, the pillar-shaped channels 501 in each of the columns of the array can be formed at lateral walls thereof with an oxidization layer 506 and a word line 507 sequentially, both of which extend along the first direction, e.g., X direction, and be thus connected to one another by the word line 507. In an embodiment, a source 504 and a drain 503 can be formed on two ends of each of the pillar-shaped channels 501, respectively. In some embodiments, the sources 504 and the drains 503 are interchangeable. In an embodiment, an electromagnetic shielding element 508 can be disposed between two neighboring one of the transistors that are disposed in a row in Y direction and extend along X direction. For example, the electromagnetic shielding elements 508 can be parallel to the word line 507.

In some embodiments, as shown in FIG. 5, at least one of the electromagnetic shielding elements 508 has a projection onto a corresponding one of the pillar-shaped channels 501 in Y direction does not overlap the source 504 and the drain 503. For example, the electromagnetic shielding element 508 has a length extending in Z direction less than a length of the pillar-shaped channel 501 and equal to or greater than one third of the length.

In some embodiments, as shown in FIG. 5, neighboring two of the pillar-shaped channels 501 have their word lines 507 formed on lateral walls thereof that face opposite directions, and one of the electromagnetic shielding elements 508 is disposed between the two pillar-shaped channels 501 at opposite lateral walls thereof to the lateral walls at which the corresponding word lines 507 are formed.

In some embodiment, the semiconductor device 500 can further include bit lines 510 that are connected to the drains 503 of the transistors, and storage capacitors 509 that are connected to the sources 504 at first terminals thereof via storage capacitor pads 505 and to a common terminal (not shown) at second terminals thereof for storing data written into the semiconductor device 500.

In some embodiments, the electromagnetic shielding elements 508 can be connected to the common terminal, and a voltage applied to the common terminal can thus be provided to the electromagnetic shielding elements 508.

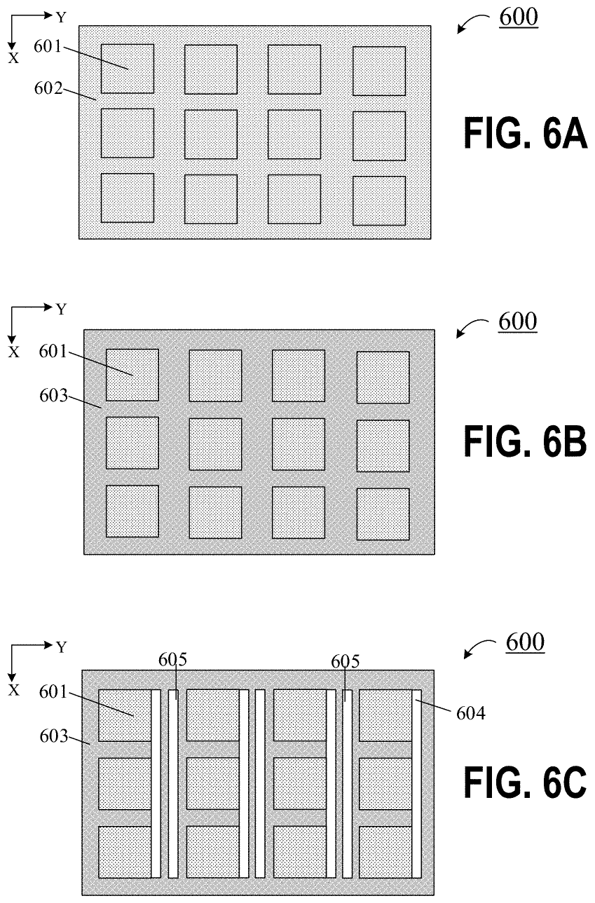

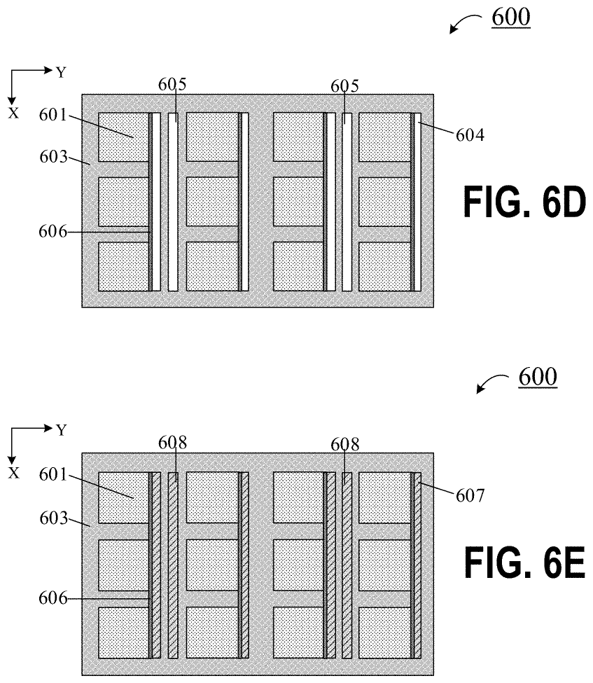

FIGS. 6A to 6E illustrate manufacturing a semiconductor device 600 according to some embodiments of the present disclosure. In the semiconductor device 600, word lines are formed on lateral walls of any two neighboring transistors (or channels) that face the same direction.

FIG. 6A is a top view illustrating the formation of pillar-shaped channels of the semiconductor device 600 according to some embodiments of the present disclosure. As shown in FIG. 6A, a plurality of channels 601 that are arranged in an array in an X-Y plane, for example, are formed on a surface of a wafer (not shown). For example, the array can include a plurality of rows that are arranged along a first direction, e.g., X direction, and a plurality of columns that intersect the rows and are arranged along a second direction, e.g., Y direction. In an embodiment, each of the channels 601 can be in the shape of a pillar, e.g., a rectangular pillar, and each of the rectangular pillar-shaped channels 401 can extend along a third direction, e.g., Z direction, that is perpendicular to a plane defined by the first direction and the second direction.

In some embodiments, the pillar-shaped channels 601 can be formed on the surface of the wafer by covering the wafer with a mask (not shown) that covers a certain area of the wafer that is used to form the pillar-shaped channels 601, etching the wafer to a certain depth, which is less than the thickness of the wafer, to form first grooves 602 that are disposed between the pillar-shaped channels 601, and removing the mask to form the pillar-shaped channels 601 with their lateral walls exposed. In some embodiments, the wafer can be etched by using photolithography (PH) or dry etching (ET), e.g., electron beam lithography, plasma etching and reactive ion etching (RIE).

FIG. 6B is a top view illustrating the formation of an insulating layer of the semiconductor device 600 according to some embodiments of the present disclosure. In some embodiments, an insulating material, e.g., SiO₂, can be deposited in the first grooves 602 to form an insulating layer 603 that covers the first grooves 602 and the lateral walls of the pillar-shaped channels 601. In some embodiments, a chemical mechanical polishing (CMP) can then be employed to polish and remove the residual of the insulating material to expose top surfaces of the pillar-shaped channels 601.

FIG. 6C is a top view illustrating the formation of second grooves and third grooves of the semiconductor device 600 according to some embodiments of the present disclosure. In an embodiment, the insulating layer 603 can be etched to form second grooves 604 that expose one of the lateral walls of each of the pillar-shaped channels 601, e.g., the rectangular pillar-shaped channels 601, and third grooves 605, each of which is disposed between two neighboring transistors (i.e., two neighboring rectangular pillar-shaped channels 601) in a row in Y direction. In some embodiments, each of the second grooves 604 exposes the lateral walls of the pillar-shaped channels 401 of the transistors that neighbor to each other and are arranged in a column in X direction. In an embodiment, the lateral walls of the two neighboring rectangular pillar-shaped channels 601 that are exposed by the corresponding two of the second grooves 604 can face the same direction, as shown in FIG. 6C. In another embodiment, the lateral walls of the two neighboring rectangular pillar-shaped channels 601 that are exposed by the corresponding two of the second grooves 604 can face opposite directions. In some embodiments, the third groove 605 and each of the two second grooves 604, between which the third groove 605 is disposed, are disposed at opposite lateral walls of the rectangular pillar-shaped channels 601, as shown in FIG. 6C.

In some embodiments, the second grooves 604 can be greater than the third grooves 605 in etching depth. The etching depths of the second grooves 604 and the third grooves 605 can be controlled by determining various etching parameters, such as etching time, gas flow rate, gas flow proportion, pressure and temperature. For example, under a constant etching rate, the longer the etching time is, the deeper the grooves formed in the third direction become, e.g., Z direction. In an embodiment, the second grooves 604 can have a greater etching depth than the third grooves 605 by controlling the etching parameters. The second grooves 604 and the third grooves 605 can be formed by dry etching, e.g., plasma etching.

FIG. 6D is a top view illustrating the formation of gate oxidization layers of the semiconductor device 600 according to some embodiments of the present disclosure. In an embodiment, the lateral walls of the rectangular pillar-shaped channels 601 that are exposed by the second grooves 604 can be oxidized, e.g., by direct oxidization, alkaline oxidization or acidic oxidization, to form gate oxidization layers 606 on the exposed lateral walls of the rectangular pillar-shaped channels 601. For example, the lateral walls of the rectangular pillar-shaped channels 601 that are exposed by the second grooves 604 can be heated and oxidized directly, so that silicon in the lateral walls reacts with air containing an oxidizing material in a high temperature to form a silicon dioxide film, i.e., the gate oxidization layers 660, on the lateral walls of the rectangular pillar-shaped channels 601. In some embodiments, the gate oxidization layers 606 can include an insulation material, such as silicon dioxide (SiO₂).

FIG. 6E is a top view illustrating the formation of electromagnetic shielding elements and word lines of the semiconductor device 600 according to some embodiments of the present disclosure. In an embodiment, the third grooves 605 and the second grooves 604 can be filled with a metal material, to form electromagnetic shielding elements 608 and word lines (or gates) 607, respectively. Therefore, the word lines 607 and the electromagnetic shielding elements 608 can be formed in a single deposition step. In another embodiment, the word lines 607 and the electromagnetic shielding elements 608 can be formed in two process steps sequentially. In some embodiment, the metal material can include, but are not limited to tungsten (W), cobalt (Co), copper (Cu), aluminum (Al), or other suitable metal materials. In an embodiment, each of the word lines 607 can electrically connect neighboring some of the transistors that are arranged in a column in X direction at the lateral walls of the pillar-shaped channels 601 thereof. In an embodiment, the gate oxidization layers 606 are disposed between the pillar-shaped channels 601 and the word lines 607 to isolate the word line 607 from the pillar-shaped channels 601 and prevent charge leakage. In an embodiment, the lateral walls of the two neighboring rectangular pillar-shaped channels 601 at which the word lines 607 are disposed can face the same direction, as shown in FIG. 6E. In another embodiment, the lateral walls of the two neighboring rectangular pillar-shaped channels 601 at which the word lines 607 are disposed can face opposite directions. In some embodiments, the electromagnetic shielding element 608 and each of the two word lines 607, between which the electromagnetic shielding element 608 is disposed, are disposed at opposite lateral walls of the rectangular pillar-shaped channels 601, as shown in FIG. 6E. The electromagnetic shielding elements 608 can prevent the neighboring pillar-shaped channels 601 from interfering with each other, and reduce the coupling effect occurring between the word lines 607 and the pillar-shaped channels 601. The word lines 607 can be applied with word line voltages, and the transistors connected thereto can be enabled or disabled.

In some embodiments, bit lines can be formed to connect the drains of the transistors. Storage capacitors are further formed to store data written into the semiconductor device 600. Each of the storage capacitors has a first electrode connected to the source of a corresponding one of the transistor, and a second electrode connected to a common terminal. In an embodiment, the common terminal can be connected to a low voltage, e.g., 0.5V. In another embodiment, the common terminal can be grounded.

In an embodiment, the electromagnetic shielding elements 608 can be connected to the common terminal. In another embodiment, the electromagnetic shielding elements 608 can be disconnected with the common terminal, and supplied with a voltage independently. In some embodiments, the electromagnetic shielding elements 608 can be grounded.

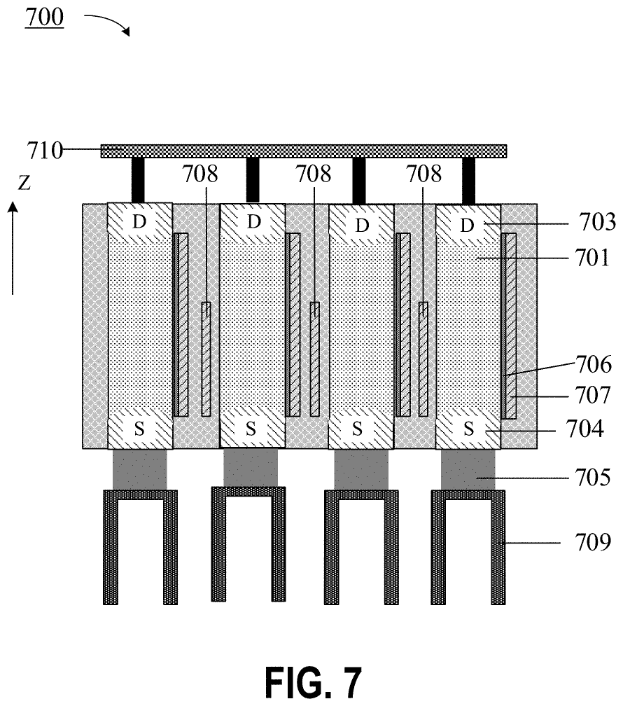

FIG. 7 is a cross-sectional view of a semiconductor device 700 according to some embodiments of the present disclosure. The semiconductor device 700 can be manufactured by the method 400. The semiconductor device 700 can include a plurality of transistors arranged in an array in an X-Y plane that is defined by a first direction, e.g., X direction, and a second direction, e.g., Y direction, each of the transistors including a channel 701, e.g., a rectangular pillar-shaped channel, extending in a third direction perpendicular to the X-Y plane, e.g., Z direction. A gate oxidization layer 706 and a word line 707 are formed sequentially at one of lateral walls of each of the rectangular pillar-shaped channels 701. The gate oxidization layers 706 are thus disposed between the rectangular pillar-shaped channels 701 and the word lines 707 to isolate the word lines 707 from the rectangular pillar-shaped channels 701 and prevent charge leakage. Each of the word lines 707 can extend along the first direction, e.g., X direction, and connect at least some of the transistors that are arranged in a column in X direction. An electromagnetic shielding element 708 is disposed between at least two neighboring transistors that are arranged in a row in Y direction. In an embodiment, the electromagnetic shielding element 708 can extend in X direction. In some embodiment, the word lines 707 and the electromagnetic shielding elements 708 are parallel. A source 704 and a drain 703 are formed on two ends of each of the pillar-shaped channels 701, respectively.

In an embodiment, as shown in FIG. 7, the electromagnetic shielding elements 708 have greater lengths than the word lines 707 along a direction in which the pillar-shaped channels 701 extend, e.g., Z direction. The lengths of the electromagnetic shielding elements 708 and the lengths of the word lines 707 can be determined by controlling the etching depths of the third grooves, e.g., the third grooves 605, and the second grooves, e.g., the second grooves 604, respectively. The etching depths of the second grooves 604 and the third grooves 605 can be controlled by determining various etching parameters, such as etching time, gas flow rate, gas flow proportion, pressure and temperature. In an embodiment, the lengths of the electromagnetic shielding elements 708 along a direction in which the pillar-shaped channels 701 extend, e.g., Z direction, is greater than one third of the lengths of the word lines 707 in Z direction.

In some embodiment, the semiconductor device 700 can further include bit lines 710 that are connected to the drains 703 of the transistors, and storage capacitors 709 that are connected to the sources 704 at first terminals thereof via storage capacitor pads 705 and to a common terminal (not shown) at second terminals thereof for storing data written into the semiconductor device 700.

In an embodiment, the electromagnetic shielding elements 708 can be connected to the common terminal, and a voltage applied to the common terminal can thus be provided to the electromagnetic shielding elements 708. In another embodiment, the electromagnetic shielding elements 708 can be disconnected with the common terminal, and supplied with a voltage independently.

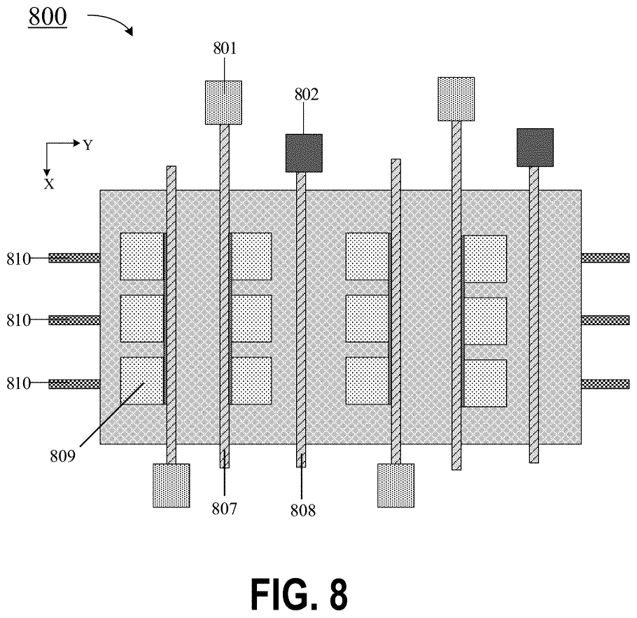

FIG. 8 is a top view illustrating the formation of contact pads of a semiconductor device 800 according to some embodiments of the present disclosure. Bit lines 810 are connected to drains of a plurality of transistors that are arranged in an array in an X-Y plane, for example. Each of the transistors has a channel 809, e.g., a rectangular pillar-shaped channel, extending in a direction, e.g., Z direction, that is perpendicular to the X-Y plane. The semiconductor device 800 can include a plurality of word lines 807 and one or more electromagnetic shielding elements 808. Each of the word lines 807 can electrically connect neighboring some of the transistors that are arranged in a column in X direction at lateral walls thereof. Each of the electromagnetic shielding elements 808 can be disposed between neighboring two of the transistors that are disposed in a row in Y direction. In an embodiment, the lateral walls of the rectangular pillars-shaped channels 809 of the two neighboring transistors at which the word lines 807 are formed face opposite directions. The semiconductor device 800 can further include word line contact pads 801 connected to the word lines 807 and electromagnetic shielding contact pads 802 connected to the electromagnetic shielding elements 808. In an embodiment, as the word line contact pads 801 and the electromagnetic shielding contact pads 802 may be greater in size than the word lines 807 and the electromagnetic shielding elements 808, respectively, any neighboring two of the word line contact pads 801 can be disposed at two opposite side of the array in X direction, and any one of the electromagnetic shielding contact pads 802 and a neighboring one of the word line contact pads 801 can be staggered with respect to each other, in order to prevent the word lines 807 and the electromagnetic shielding elements 808 from being in contact with each other.

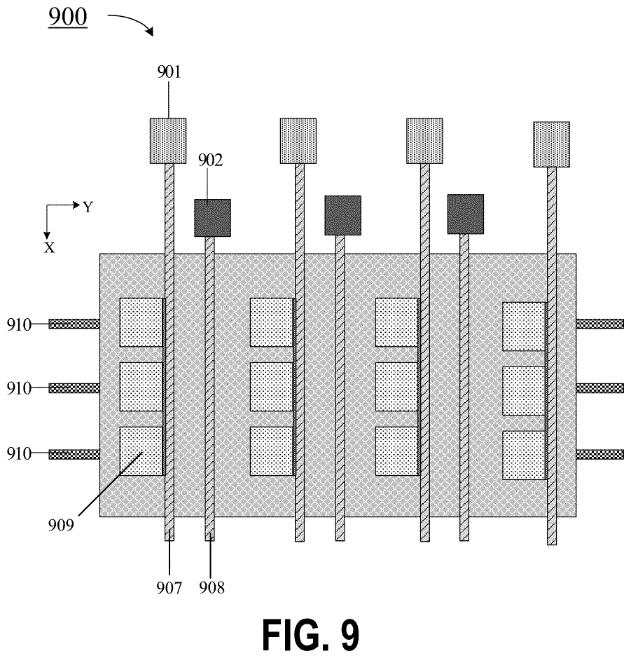

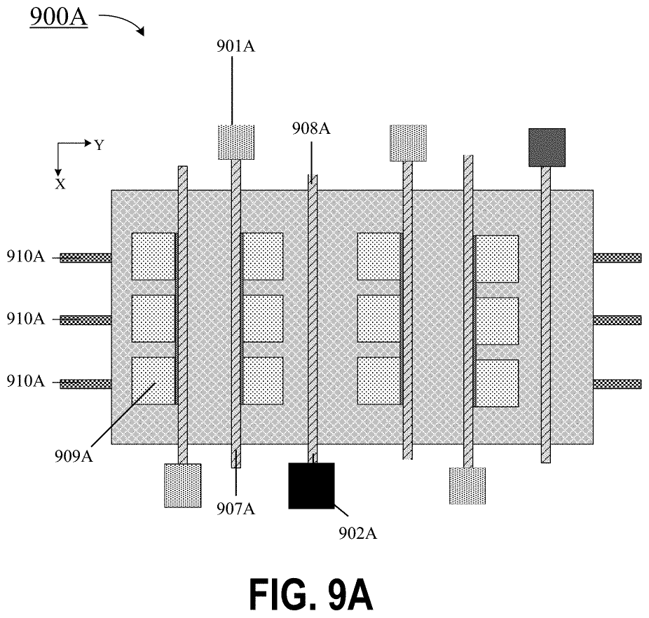

FIG. 9 is a top view illustrating the formation of contact pads of a semiconductor device 900 according to some embodiments of the present disclosure. Bit lines 910 are connected to source or drains of a plurality of transistors that are arranged in an array in an X-Y plane, for example. Each of the transistors has a channel 909, e.g., a rectangular pillar-shaped channel, extending in a direction, e.g., Z direction, that is perpendicular to the X-Y plane. The semiconductor device 900 can include a plurality of word lines 907 and one or more electromagnetic shielding elements 908. Each of the word lines 907 can electrically connect neighboring some of the transistors that are arranged in a column in X direction at lateral walls thereof. Each of the electromagnetic shielding elements 908 can be disposed between neighboring two of the transistors that are disposed in a row in Y direction. In an embodiment, the lateral walls of the rectangular pillars-shaped channels 909 of the two neighboring transistors at which the word lines 907 are formed face the same direction. The semiconductor device 900 can further include word line contact pads 901 connected to the word lines 907 and electromagnetic shielding contact pads 902 connected to the electromagnetic shielding elements 908. In some embodiments, the word line contact pads 901 and the electromagnetic shielding contact pads 902 are disposed at the same side of the array in X direction, and any one of the electromagnetic shielding contact pads 902 and a neighboring one of the word line contact pads 901 are staggered with respect to each other.

FIG. 9A is a top view illustrating the formation of contact pads of a semiconductor device 900A according to some embodiments of the present disclosure. Bit lines 910A are connected to source or drains of a plurality of transistors that are arranged in an array in an X-Y plane, for example. Each of the transistors has a channel 909A, e.g., a rectangular pillar-shaped channel, extending in a direction, e.g., Z direction, that is perpendicular to the X-Y plane. The semiconductor device 900A can include a plurality of word lines 907A and one or more electromagnetic shielding elements 908A. Each of the word lines 907A can electrically connect neighboring some of the transistors that are arranged in a column in X direction at lateral walls thereof. Each of the electromagnetic shielding elements 908A can be disposed between neighboring two of the transistors that are disposed in a row in Y direction. In an embodiment, the lateral walls of the rectangular pillars-shaped channels 909A of the two neighboring transistors at which the word lines 907A are formed face the same direction. The semiconductor device 900A can further include word line contact pads 901A connected to the word lines 907A and electromagnetic shielding contact pads 902A connected to the electromagnetic shielding elements 908A. In some embodiments, any neighboring two of the word line contact pads 901A and the electromagnetic shielding contact pads 902A are disposed at opposite sides of the array in X direction, in order to prevent the word lines 907A and the electromagnetic shielding elements 908 from being in contact with each other. For example, as shown in FIG. 9A, the electromagnetic shielding contact pad 902A is disposed at a back side of the array in X direction, while the word line contact pad 901A, which neighbors the electromagnetic shielding contact pad 902A, is disposed at a front side of the array in X direction.

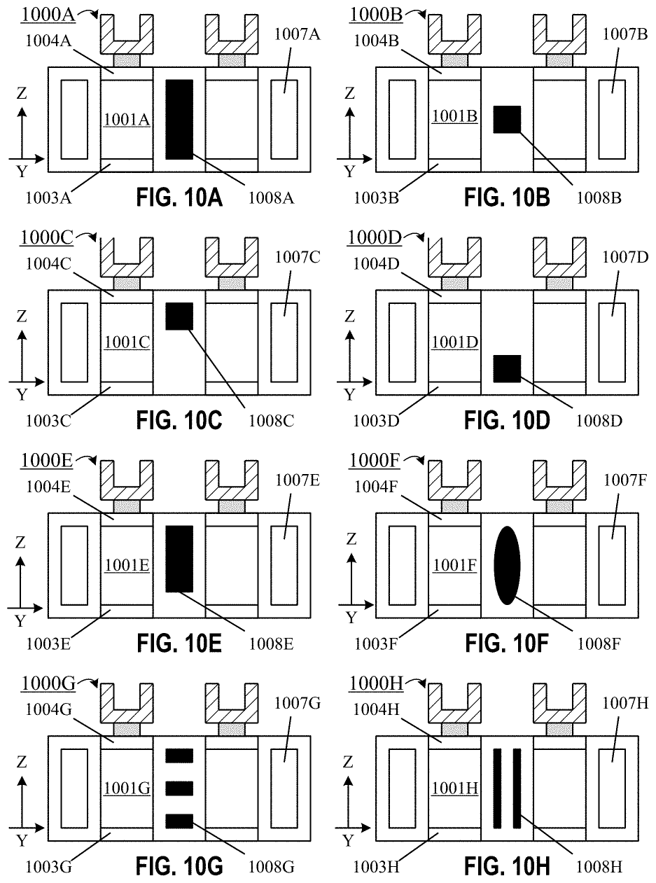

FIGS. 10A to 10H are cross-sectional views of semiconductor devices 1000A to 1000H that have electromagnetic shielding elements 1008A to 1008H in various configurations according to some embodiments of the present disclosure. The semiconductor device 1000A/1000B/1000C/1000D/1000E/1000F/1000G/1000H includes a plurality of transistors arranged in an X-Y plane, for example, each of the transistors including a channel 1001A/1001B/1001C/1001D/1001E/1001F/1001G/1001H, e.g., a rectangular pillar-shaped channel, extending in Z direction, and a source 1004A/1004B/1004C/1004D/1004E/1004F/1004G/1004H and a drain 1003A/1003B/1003C/1003D/1003E/1003F/1003G/1003H formed on two ends of the pillar-shaped channels 1001A/1001B/1001C/1001D/1001E/1001F/1001G/1001H, respectively, a plurality of word lines 1007A/1007B/1007C/1007D/1007E/1007F/1007G/1007H each of which electrically connects neighboring some of the transistors that are arranged in a column in X direction at lateral walls of the pillar-shaped channels 1001A/1001B/1001C/1001D/1001E/1001F/1001G/1001H, and one or more electromagnetic shielding elements 1008A/1008B/1008C/1008D/1008E/1008F/1008G/1008H each of which is disposed between neighboring two of the transistors in a row in Y direction. The electromagnetic shielding elements can have projections onto the pillar-shaped channels in Y direction and be equal to the pillar-shaped channels in length, e.g., the electromagnetic shielding element 1008A, or be less than the pillar-shaped channels in length, e.g., the electromagnetic shielding elements 1008B, 1008C and 1008D, which can be disposed in middle, upper and lower regions, respectively, with respect to the pillar-shaped channels 1001B, 1001C and 1001D. The electromagnetic shielding elements can have a cross section in the shape of a rectangle, e.g., the electromagnetic shielding element 1008A to 1008E, 1008G and 1008H, or an oval, e.g., the electromagnetic shielding element 1008F. The electromagnetic shielding elements each can include a plurality of electromagnetic shielding segments that are separated from one another and arranged along Z direction, e.g., electromagnetic shielding element 1008G, and/or Y direction, e.g., electromagnetic shielding element 1008H.

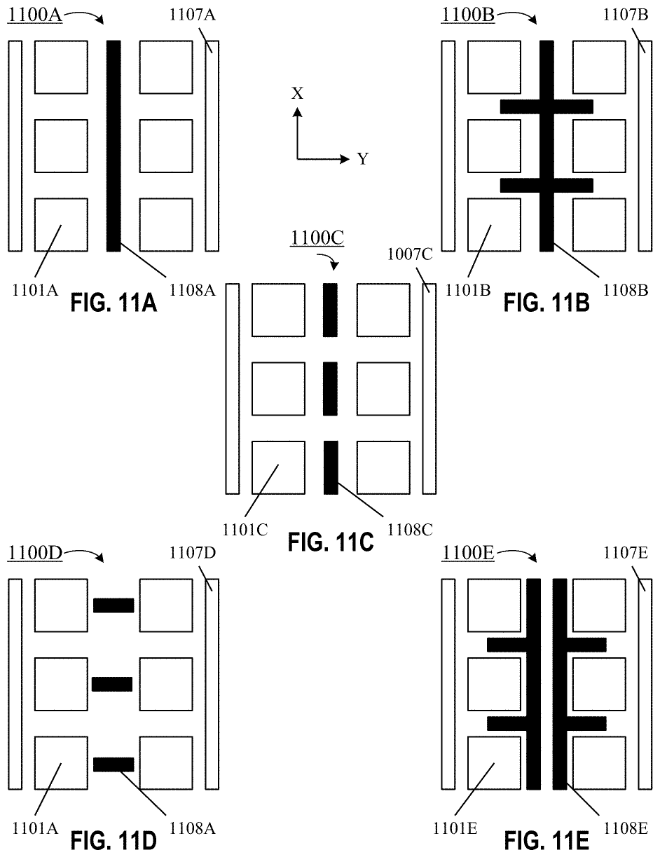

FIGS. 11A to 11E are cross-sectional views of semiconductor devices 1100A to 1100E that have electromagnetic shielding elements 1108A to 1108E in various configurations according to some embodiments of the present disclosure. The semiconductor device 1100A/1100B/1100C/1100D/1100E includes a plurality of transistors arranged in an X-Y plane, for example, each of the transistors including a channel 1101A/1101B/1101C/1101D/1101E, e.g., a rectangular pillar-shaped channel, extending in Z direction, and a source and a drain (not shown) formed on two ends of the pillar-shaped channels 1101A/1101B/1101C/1101D/1101E, respectively, a plurality of word lines 1107A/1107B/1107C/1107D/1107E each of which electrically connects neighboring some of the transistors that are arranged in a column in X direction at lateral walls of the pillar-shaped channels 1101A/1101B/1101C/1101D/1101E, and one or more electromagnetic shielding elements 1108A/1108B/1108C/1108D/1108E each of which is disposed between neighboring two of the transistors in a row in Y direction. The electromagnetic shielding elements each can include a plurality of electromagnetic shielding segments that are separated from one another and arranged along Y direction, e.g., the electromagnetic shielding element 1108E, or along X direction, e.g., the electromagnetic shielding elements 1108C and 1108D, the electromagnetic shielding segments of which can extend in X direction and/or Y direction, as shown in FIGS. 11C and 11D, respectively. The electromagnetic shielding elements can be further disposed between neighboring two of the transistors that are disposed in the column in X direction, e.g., electromagnetic shielding elements 1108B and 1108E.

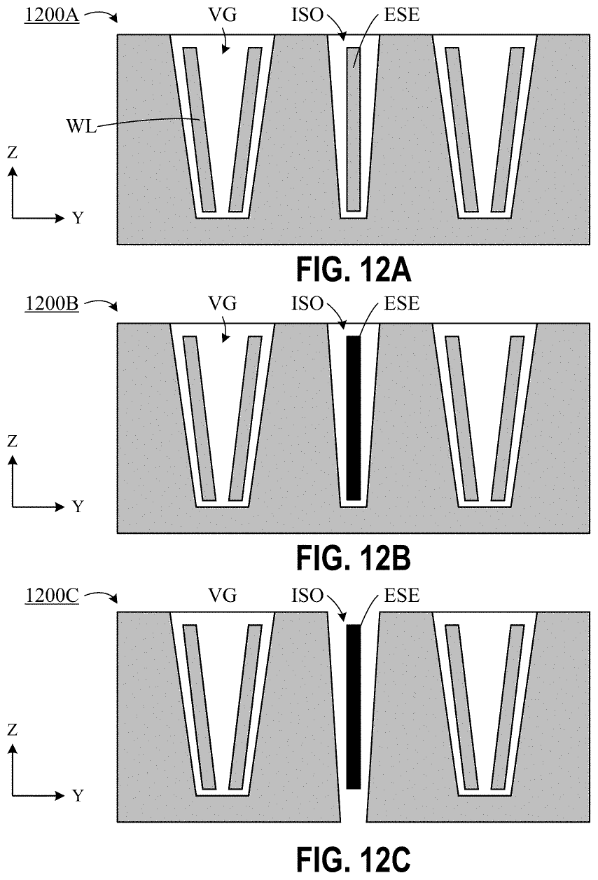

FIGS. 12A to 12C are cross-sectional views illustrating manufacturing semiconductor devices according to some embodiments of the present disclosure. In an embodiment, the electromagnetic shielding elements and the word lines can be formed at the same time in a single process. For example, as shown in FIG. 12A, vertical gate grooves (or trenches) VG (e.g., the second grooves 404) and isolation grooves (or trenches) ISO (e.g., the third grooves 405) that are narrower than the vertical gate grooves VG, can be formed in a substrate, an oxide layer, e.g., the gate oxidization layer 406, can be formed on exposed lateral walls of the vertical gate grooves VG and the isolation grooves ISO, and a conductor, e.g., a metal material or polysilicon, can be deposited in the vertical gate grooves VG and the isolation grooves ISO at the same time to form word lines WL (e.g., the word lines 407) and electromagnetic shielding elements ESE (e.g., the electromagnetic shielding elements 408) of a semiconductor device 1200A, respectively.

In another embodiment, as shown in FIG. 12B, word lines WL and electromagnetic shielding elements ESE of a semiconductor device 1200B can be formed sequentially. For example, vertical gate grooves VG can be formed in a substrate, an oxide layer can be formed on exposed lateral walls of the vertical gate grooves VG, and a first conductor can be deposited in the vertical gate grooves VG, to form the word lines WL; and isolation grooves ISO can be etched and formed in the substrate, an oxide liner can be deposited on exposed lateral walls of the isolation grooves ISO, and a second conductor can be deposited to fill the isolation grooves ISO, to form the electromagnetic shielding elements ESE.

In some embodiments, as shown in FIG. 12C, word lines WL and electromagnetic shielding elements ESE of a semiconductor device 1200C can be formed individually. For example, grooves for contact pads, e.g., the electromagnetic shielding contact pads 902A shown in FIG. 9A, to be formed therein can be formed and filled with oxide, and vertical gate grooves VG and isolation grooves ISO can then be etched by a self-aligned double patterning (SADP), for example. Therefore, a portion of the isolation grooves ISO where the electromagnetic shielding contact pads are to be formed on a back side of the semiconductor device 1200C can be deeper than the vertical gate grooves VG, and a remaining of the isolation grooves ISO can be as deep as the vertical gate grooves VG. Subsequently, an oxide layer and a first conductor can be formed in the vertical gate grooves VG sequentially to form the word lines WL, the back side of the semiconductor device 1200C can be thinned to expose the oxide filled in the isolation grooves ISO, the oxide can then be recessed, an oxide liner can be deposited on exposed lateral walls of the isolation grooves ISO, and a second conductor can fill the isolation grooves ISO and a space that is formed after the oxide is recessed to form the electromagnetic shielding elements ESE and the electromagnetic shielding contact pad, respectively.

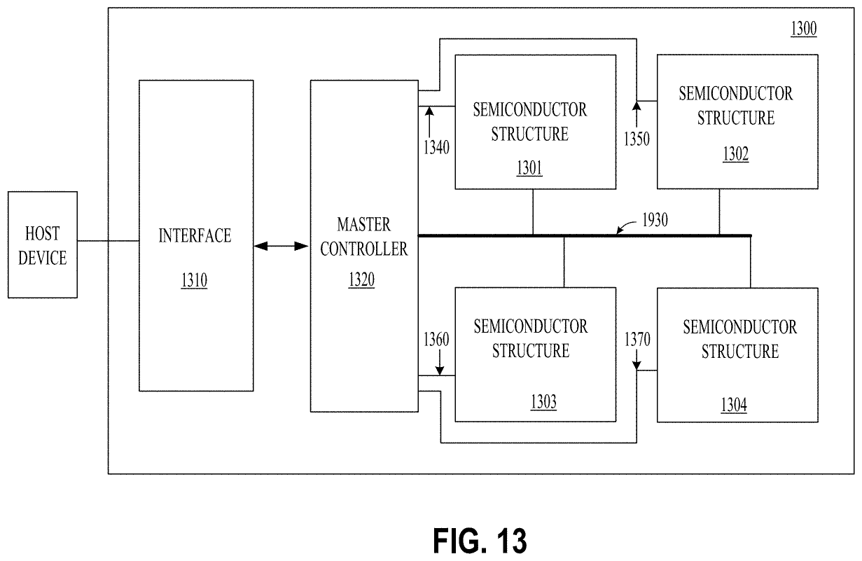

FIG. 13 shows a block diagram of a memory system 1300 in accordance with some embodiments of the present disclosure. The memory system 1300 can includes one or more semiconductor devices 1301 to 1304, e.g., the semiconductor devices 400A, 500, 600, 700, 800, 900A, 1000A-1000H, 1100A-1100E and 1200A-1200C. In some embodiments, the memory system 1300 can be a solid state drive (SSD) or a memory module.

The memory system 1300 can include other suitable components. For example, the memory system 1300 can include an interface (or master interface circuitry) 1310 and a master controller (or control circuitry) 1320 coupled to each other. The memory system 1300 can also include a bus 1330 that couples the master controller 1320 with the semiconductor devices 1301 to 1304. In addition, the master controller 1320 is connected with the semiconductor devices 1301 to 1304, respectively, such as shown by respective control lines 1340-1370.

The interface 1310 is suitably configured mechanically and electrically to connect between the memory system 1300 and a host device, and can be used to transfer data between the memory system 1300 and the host device.

The master controller 1320 is configured to connect the respective semiconductor devices 1301 to 1304 to the interface 1310 for data transfer. For example, the master controller 1320 can be configured to provide enable/disable signals respectively to the semiconductor devices 1301 to 1304 to activate one or more of the semiconductor devices 1301 to 1304 for data transfer.

The master controller 1320 is responsible for the completion of various instructions within the memory system 1300. For example, the master controller 1320 can perform bad block management, error checking and correction, garbage collection, and the like. In some embodiments, the master controller 1320 can be implemented using a processor chip. In some examples, the master controller 1320 can be implemented using multiple master control units (MCUs).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a plurality of transistors that are arranged in an array in an X-Y plane, each of the transistors including a channel extending in Z direction;
forming a plurality of word lines, each of which electrically connects neighboring some of the transistors at lateral walls of the channels thereof, the neighboring some of the transistors being arranged in a column in X direction; and
forming one or more electromagnetic shielding elements, at least one of which is disposed between neighboring two of the transistors that are disposed in a row in Y direction.

2. The method of claim 1, wherein each of the transistors further includes a source disposed on a first end of the channel and a drain disposed on a second end of the channel, and the electromagnetic shielding element has a projection onto the channel in Y direction that does not overlap the source and the drain.

3. The method of claim 1, wherein the electromagnetic shielding element is shorter in Z direction than the channels of the neighboring two transistors.

4. The method of claim 1, wherein the electromagnetic shielding element is further disposed between neighboring two of the transistors that are disposed in the column.

5. The method of claim 1, wherein each of the channels of the transistors is rectangular pillar-shaped, and each of the word lines is formed at a lateral wall of a corresponding one of the rectangular pillar-shaped channels.

6. The method of claim 5, wherein the lateral walls of the rectangular pillar-shaped channels of the neighboring two transistors at which the word lines are formed face opposite directions.

7. The method of claim 1, further comprising:
forming an electromagnetic shielding contact pad that is connected to one of the electromagnetic shielding elements; and
forming a word line contact pad that is connected to one of the word lines that neighbors the electromagnetic shielding element,
wherein the electromagnetic shielding contact pad and the word line contact pad are disposed at opposite sides of the array in X direction.

8. The method of claim 7, wherein the electromagnetic shielding elements and the word lines are formed by:
forming first grooves in a substrate of the semiconductor device at a back side thereof for contact pads to be formed therein, and filling the first grooves with an oxide;
forming in the substrate second grooves and third grooves for the word lines and the electromagnetic shielding elements to be formed therein, respectively, the third grooves being in contact with the first grooves;
filling the second grooves with a first conductor to form the word lines;
thinning the back side of the semiconductor device to expose the oxide filled in the first grooves;
recessing the oxide to expose lateral walls of the third grooves; and
filling the third grooves and the first grooves with a second conductor to form the electromagnetic shielding elements and the contact pads, respectively.

9. A semiconductor device, comprising:
a plurality of transistors that are arranged in an array in an X-Y plane, each of the transistors including a channel extending in Z direction;
a plurality of word lines, each of which electrically connects neighboring some of the transistors that are arranged in a column in X direction at lateral walls of the channels thereof; and
one or more electromagnetic shielding elements, at least one of which is disposed between neighboring two of the transistors that are disposed in a row in Y direction.

10. The semiconductor device of claim 9, wherein each of the transistors further includes a source disposed on a first end of the channel and a drain disposed on a second end of the channel, and the electromagnetic shielding element has a projection onto the channel in Y direction that does not overlap the source and the drain.

11. The semiconductor device of claim 9, wherein the electromagnetic shielding element is shorter in Z direction than the channels of the neighboring two transistors.

12. The semiconductor device of claim 9, wherein the electromagnetic shielding element is further disposed between neighboring two of the transistors that are disposed in the column.

13. The semiconductor device of claim 9, wherein each of the channels of the transistors is rectangular pillar-shaped, and each of the word lines is formed at a lateral wall of a corresponding one of the rectangular pillar-shaped channels.

14. The semiconductor device of claim 13, wherein the lateral walls of the rectangular pillar-shaped channels of the neighboring two transistors on which the word lines are formed face opposite directions.

15. The semiconductor device of claim 9, further comprising:
an electromagnetic shielding contact pad connected to one of the electromagnetic shielding elements; and
a word line contact pad connected to one of the word lines that neighbors the electromagnetic shielding element,
wherein the electromagnetic shielding contact pad and the word line contact pad are e disposed at opposite sides of the array in X direction.

16. The semiconductor device of claim 9, wherein at least one of the electromagnetic shielding elements includes a plurality of electromagnetic shielding segments that are separated from one another.

17. The semiconductor device of claim 16, wherein the electromagnetic shielding segments are arranged along X direction, Y direction and/or Z direction.

18. The semiconductor device of claim 9, wherein at least one of the electromagnetic shielding elements is applied with a first voltage that is less than a second voltage applied to a corresponding one of the channels.

19. The semiconductor device of claim 9, wherein at least one of the electromagnetic shielding elements is applied with a voltage such that a first transistor of the neighboring two transistors, between which the electromagnetic shielding element is disposed, is less affected by a combination of a first electromagnetic field generated by the electromagnetic shielding element with a second electromagnetic field generated by a second transistor of the neighboring two transistors than affected by the second electromagnetic field.

20. A memory system, comprising:
a semiconductor device, including:
a plurality of transistors that are arranged in an array in an X-Y plane, each of the transistors including a channel extending in Z direction;
a plurality of word lines, each of which electrically connects neighboring some of the transistors that are arranged in a column in X direction at lateral walls of the channels thereof; and
one or more electromagnetic shielding elements, at least one of which is disposed between neighboring two of the transistors that are disposed in a row in Y direction; and
control circuitry coupled to the semiconductor device, the control circuitry configured for controlling operations of the semiconductor device.
